(19) United States
(12) Patent Application Publication
(10) Pub. No.: US 2012/0104571 A1
(43) Pub. Date: May 3, 2012

(54) SEMICONDUCTOR PACKAGE AND MANUFACTURING METHOD THEREOF

(75) Inventor: Jin O. YOO, Gyunggi-do (KR)

(73) Assignee: SAMSUNG ELECTRO-MECHANICS CO., LTD.

(21) Appl. No.: 13/275,960

(22) Filed: Oct. 18, 2011

(30) Foreign Application Priority Data
Oct. 27, 2010 (KR) 10-2010-0105384

(51) Int. Cl. H01L 23/552; H01L 21/78

(52) U.S. Cl. 257/659; 438/113; 257/E23.114; 257/E21.599

(57) ABSTRACT

There are provided a semiconductor package including an electromagnetic shielding structure having excellent electromagnetic interference (EMI) and electromagnetic susceptibility (EMS) characteristics, while protecting individual elements in an inner portion thereof from impacts, and a manufacturing method thereof. The semiconductor package includes: a substrate having ground electrodes formed on an upper surface thereof; at least one electronic component mounted on the upper surface of the substrate; an insulating molding part including an internal space in which the electronic component is accommodated, and fixed to the substrate such that at least a portion of the ground electrode is externally exposed; and a conductive shield part closely adhered to the molding part to cover an outer surface of the molding part and electrically connected to the externally exposed ground electrodes.

### CROSS-REFERENCE TO RELATED APPLICATIONS

This application claims the priority of Korean Patent Application No. 10-2010-0105384 filed on Oct. 27, 2010, in the Korean Intellectual Property Office, the disclosure of which is incorporated herein by reference.

### BACKGROUND OF THE INVENTION

1. Field of the Invention

The present invention relates to a semiconductor package module and a manufacturing method thereof, and more particularly, to a semiconductor package module including a shielding member capable of shielding electromagnetic waves, while simultaneously protecting a passive element, a semiconductor chip, or the like, included in a package, from an external environment, and a manufacturing method thereof.

2. Description of the Related Art

In accordance with a recent rapid increase in market demand for portable electronic apparatuses, the demand for the miniaturization and lightness of electronic components mounted in these products has accordingly continuously increased.

In order to realize the miniaturization and lightening of electronic components, a system on chip (SOC) technology, capable of integrating a plurality of individual elements into a single chip, a system in package (SIP) technology integrating a plurality of individual elements into a single package, or the like, as well as various technologies reducing the individual sizes of mounted components have been required.

Particularly, there has been demand for a high frequency semiconductor package using a high frequency signal for a device such as a portable TV (DMB or DVB) module or a network module including various electromagnetic shielding structures, in order to implement excellent electromagnetic interference (EMI) or electromagnetic susceptibility characteristics as well as product miniaturization.

The general high frequency semiconductor package according to the related art has individual electronic elements mounted on a substrate and then a molding part, provided in order to protect these electronic elements, is formed thereon by applying a resin. In addition, a structure forming a shield on an outer surface of the molding part is well known in the art as a high frequency shielding structure. The shield applied to a general high frequency semiconductor package not only covers the entirety of the individual electronic elements so as to protect the electronic elements therein from external impacts, but is also electrically connected to a ground to promote electromagnetic wave shielding.

The shield according to the related art is configured to be electrically connected to a ground pattern of the substrate. At this time, a connection portion between the ground pattern of the substrate and the shield is formed to have a very fine pattern, whereby the connection portion may be easily damaged due to external impacts, or the like.

In addition, in a semiconductor package according to the related art, the molding part is entirely encloses the individual elements. When the semiconductor package passes through an oven at a high temperature in the state in which the filling of the molding part or a bonding portion between the molding part and the substrate is not completely performed, high internal pressure may be generated in the bonding portion between the individual elements and the substrate due to the high temperature, and the molding part may be damaged due to the high internal pressure.

Accordingly, a semiconductor package capable of solving these defects and a manufacturing method thereof has been required.

### SUMMARY OF THE INVENTION

An aspect of the present invention provides a semiconductor package including an electromagnetic shielding structure having excellent electromagnetic interference (EMI) and electromagnetic susceptibility (EMS) characteristics, while protecting individual elements in an inner portion thereof from impacts, and a manufacturing method thereof.

Another aspect of the present invention provides a semiconductor package capable of easily grounding a shield and a substrate, and a manufacturing method thereof.

Another aspect of the present invention provides a semiconductor package in which a molding part is not damaged due to internal pressure although a high temperature is applied to the semiconductor package, and a manufacturing method thereof.

According to an aspect of the present invention, there is provided a semiconductor package, including: a substrate having ground electrodes formed on an upper surface thereof; at least one electronic component mounted on the upper surface of the substrate; an insulating molding part including an internal space in which the electronic component is accommodated, and fixed to the substrate such that at least a portion of the ground electrode is externally exposed; and a conductive shield part closely adhered to the molding part to cover an outer surface of the molding part and electrically connected to the externally exposed ground electrodes.

The ground electrodes may be formed on the substrate along edges thereof.

The molding part may be formed to have a cap shape.

The molding part may include flanges protruded to be parallel with the upper surface of the substrate on a lower end surface thereof being in contact with the upper surface of the substrate.

According to another aspect of the present invention, there is provided a manufacturing method of a semiconductor package, the manufacturing method including: preparing a substrate having ground electrodes formed on an upper surface thereof; mounting electronic components on the upper surface of the substrate; seating a molding part having a cap shape on the substrate such that a portion of the ground electrodes is externally exposed; and forming a conductive shield part on an outer surface of the molding part, the conductive shield part being electrically connected to the externally exposed ground electrodes.

The forming of the conductive shield part may include forming the conductive shield part through a conformal coating method.

The forming of the conductive shield part may include forming the conductive shield part through a screen printing method.

The ground electrodes may be formed on the substrate along edges thereof.

The preparing of the substrate may include preparing a strip substrate having a plurality of individual semiconductor package regions formed thereon.

The mounting of the electronic components may include mounting the electronic components for each of the plurality of individual semiconductor package regions.

The seating of the molding part may include seating a molding strip formed by connecting a plurality of molding parts on the strip substrate.

The forming of the conductive shield part may include forming the conductive shield part over the upper surface of the strip substrate on which the molding strip is seated.

The manufacturing method may further include dividing the strip substrate into individual semiconductor packages by cutting the strip substrate according to the individual semiconductor package regions using a blade after the forming of the shield part.

The dividing of the strip substrate may include cutting the strip substrate such that a cutting surface of the cut substrate and a side of the shield part are positioned on different planes.

The molding part may be formed to have a smaller area than that of the substrate.

The seating of the molding part may include adhering the molding part to the substrate with an adhesive.

The shield part may be a conductive adhesive, and the molding part may be fixedly bonded to the substrate by the shield part.

The molding strip may include: a plurality of molding parts; and a plurality of interconnectors interconnecting tap portions of the molding parts, an empty space being formed between two adjacently disposed interconnectors.

A width of the empty space formed between the interconnectors may be larger than a thickness of the blade.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view showing a semiconductor package according to an exemplary embodiment of the present invention;

FIG. 2 is a partially exploded perspective view showing an inner portion of the semiconductor package shown in FIG. 1;

FIGS. 3 through 9B are process cross-sectional views showing a manufacturing method of a semiconductor package according to a process sequence according to an exemplary embodiment of the present invention; and

FIG. 10 is a flow chart shown a manufacturing method of a semiconductor package according to an exemplary embodiment of the present invention.

### DETAILED DESCRIPTION OF THE PREFERRED EMBODIMENT

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention. Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, exemplary embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component does not exactly reflect its real size.

Hereinafter, exemplary embodiments of the present invention will be described in detail with reference to the accompanying drawings.

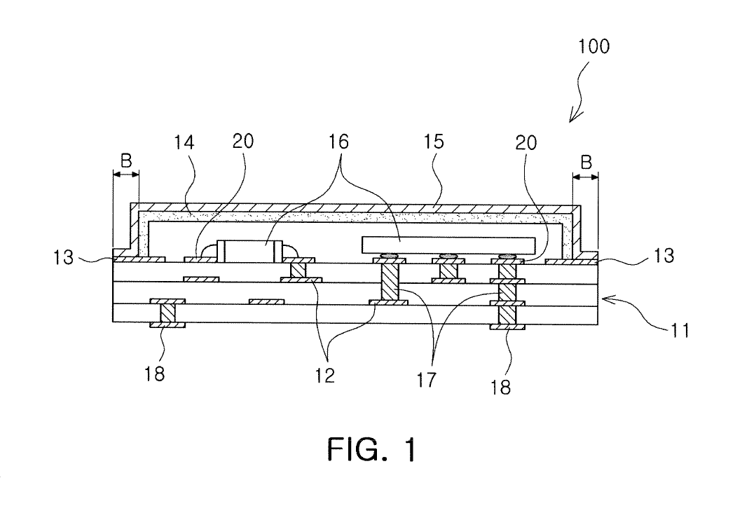

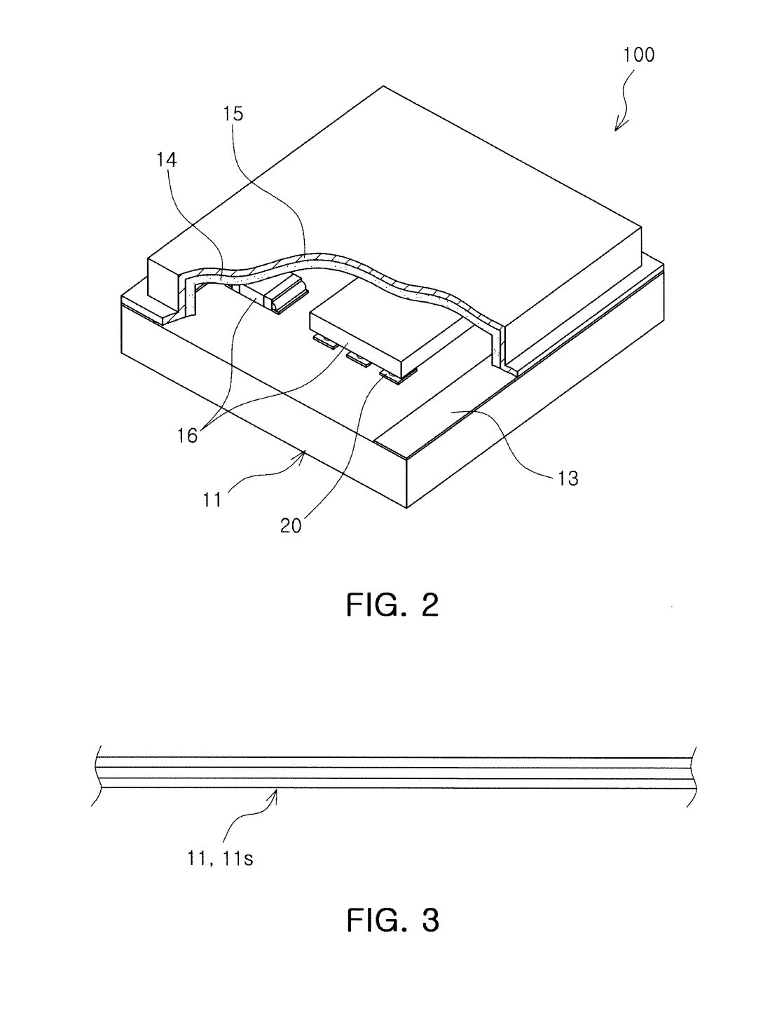

FIG. 1 is a cross-sectional view showing a semiconductor package according to an exemplary embodiment of the present invention, and FIG. 2 is a partially exploded perspective view showing an inner portion of the semiconductor package shown in FIG. 1.

As shown in FIGS. 1 and 2, a semiconductor package 10 according to an exemplary embodiment of the present invention is configured to include a substrate 11, ground electrodes 13, electronic components 16, a molding part 15, and a shield part 15.

The substrate 11 has at least one electronic component 16 mounted on an upper surface thereof. As the substrate 11, various kinds of substrates (for example, a ceramic substrate, a printed circuit board (PCB), a flexible substrate, or the like) well known in the art may be used.

The upper surface of the substrate 11 may have mounting electrodes 20 formed thereon, the mounting electrodes 20 for mounting the electronic components 16 or wiring patterns (not shown) electrically interconnecting the mounting electrodes 20. Further, the substrate 11 may be a multi-layer substrate formed as a plurality of layers, and the circuit patterns 12 for forming electrical connections may be formed between each of the plurality of layers.

In addition, the substrate 11 according to an exemplary embodiment of the present invention has ground electrodes 13 formed on the upper surface thereof. Each of the ground electrodes 13, according to the exemplary embodiment of the present invention, is formed to be elongated along at least any one of the four sides of the substrate 11 on an upper surface thereof. That is, as shown in FIG. 2, the ground electrodes 13 may be formed along both opposite sides of the substrate 11 on the upper surface thereof; however, the present invention is not limited thereto. The ground electrodes 13 may be formed along all of four sides of the substrate 11 on the upper surface thereof. In this case, the ground electrodes 13 are formed to have a rectangular shape according to an external shape of the substrate. Sides of the ground electrodes 13 according to the exemplary embodiment of the present invention may be formed on the substantially same plane as the sides of the substrate 110 to be exposed to the sides of the substrate 11.

Meanwhile, a case in which each of the ground electrodes 13 is formed to have an elongated rectangular shape having a predetermined width along at least any one of the four sides of the substrate 11 on the upper surface thereof is shown by way of example in FIGS. 1 and 2. However, the present invention is not limited thereto. When the ground electrode 13 needs to be electrically connected to a terminal of the electronic component 16, the ground electrode 13 is formed such that a portion thereof is protruded to a lower portion of the electronic component 16, whereby the protruded portion of the ground electrode 13 may be electrically connected to the terminal (that is, a ground terminal) of the electronic component 16.

In addition, a case in which two ground electrodes 13, respectively formed on both opposite sides of the substrate 11 are formed to have the same width is shown by way of example in FIGS. 1 and 2. However, the present invention is not limited thereto. That is, the ground electrodes 13 may be formed to have various sizes of widths as needed. For example, each of the ground electrodes 13 may be formed to have a different width as needed.

In addition, the substrate 11 according to the exemplary embodiment of the present invention may include external connection terminals 18 electrically connected to the mounting electrodes 20, the circuit patterns 12, the ground electrodes 13, and the like, formed on the upper surface thereof, and conductive via-holes 17 electrically interconnecting external connection terminals 18 with the mounting electrodes 20, the circuit patterns 12, and the ground electrodes 13. Furthermore, the substrate 11 according to the exemplary embodiment of the present invention may also have a cavity formed therein, the cavity being capable of mounting the electronic components in the inner portion of the substrate 11.

The electronic components 16 may include various electronic elements such as a passive element and an active element, and all electronic elements capable of being mounted on the substrate 11 or capable of being embedded in the inner portion of the substrate 11 may be used as the electronic components 16.

The molding part 14 accommodates the electronic components 16 mounted on the substrate 11, internally, and is coupled to the substrate 11. To this end, the molding part according to the exemplary embodiment of the present invention is formed to have a cap shape having a space formed internally, wherein the electronic components 16 are accommodated in the space.

The molding part 14 is coupled to the substrate 11 in such a manner as to enclose the electronic components 16 from the outside along the external shape of the substrate 11. Accordingly, the molding part 14 may protect the electronic components 16 form external impacts. The molding part 14 may be made of an insulating material including a resin material such as an epoxy, or the like.

Herein, the molding part 14 according to the exemplary embodiment of the present invention is not formed by injecting the resin material, or the like, directly onto the substrate as in the related art. That is, the molding part 14 according to the exemplary embodiment of the present invention is separately manufactured, and is then coupled to the substrate 11. Accordingly, the molding part 14 may be easily formed to have the cap shape.

In addition, the molding part 14 according to the exemplary embodiment of the present invention is formed to have the entire area (particularly, an area of a lower surface) smaller than an area of the upper surface of the substrate 11. Accordingly, when the molding part 14 is seated on the substrate 11, a portion of the substrate is exposed externally of the molding part 14.

As described above, edge portions of the substrate 11 according to the exemplary embodiment of the present invention have the ground electrodes 13 formed thereon. Accordingly, when the molding part 14 is seated on the substrate 11, exposed regions B of the ground electrodes 13 are exposed externally of the molding part 14. These exposed regions B of the ground electrodes 13 are electrically connected to the shield part 15 described below.

The shield part 15 accommodates the electronic components 16 internally, and is formed externally of the molding part 14 to shield unnecessary electromagnetic waves introduced from the outside of the substrate 11. In addition, the shield part 15 shields the electromagnetic waves generated from the electronic components 16 from being radiated to the outside. The shield part 15 is closely adhered to the molding part 14 and is formed to cover the outer surface of the molding part 14.

The shield part 15 is essentially grounded in order to shield the electromagnetic waves. To this end, in the semiconductor package 10 according to the exemplary embodiment of the present invention, the shield part 15 is configured to be electrically connected to the ground electrodes 13. More specifically, the shield part 15 according to the exemplary embodiment of the present invention is electrically connected to the exposed regions B of the ground electrodes 13 exposed to externally of the molding part 14 on the upper surface of the substrate 11.

The shield part 15 according to the exemplary embodiment of the present invention may be made of various materials having conductivity, and may be formed to have a form of a metal case. However, the present invention is not limited thereto. That is, the shield part 15 according to the exemplary embodiment of the present invention may be made of a resin material including conductive powders, or may be completed by directly forming a metal thin film. When the metal thin film is formed, various methods such as a sputtering method, a vapor deposition method, an electroplating method, an electroless plating method may be used.

In addition, the shield part 15 may be a metal thin film formed through a conformal coating method. The conformal coating method has advantages in that it may form a uniform coating film and is inexpensive as compared to other processes. In addition, the shield part 15 may be a metal thin film formed through a screen printed method.

The semiconductor package 10 according to the exemplary embodiment of the present invention configured as described above may not only protect the electronic components 16 mounted on the substrate 11 from external force by the molding part 14, but may also further improve an electromagnetic wave shielding effect by the shield part 15 formed on the outer surface of the molding part 14.

In addition, the ground electrodes 13 formed on the upper surface of the substrate 11 are used in order to ground the shield part 15 for shielding the electromagnetic waves, whereby the shield part 15 may be easily grounded.

Further, in the semiconductor package 10 according to the exemplary embodiment of the present invention, the molding part 14 is formed to have the cap shape having an empty space formed inwardly thereof, such that an empty space is formed between the electronic components 16. Therefore, although a high temperature is applied to the semiconductor package 10, internal pressure is released due to the empty space formed internally of the molding part 14, whereby damage of the semiconductor package 10 due to the internal pressure as in the related art may be prevented.

Meanwhile, the semiconductor package 10 according to an exemplary embodiment of the present invention may be formed as an individual semiconductor package 10 by simultaneously forming a plurality of semiconductor packages 10 on a strip-shaped substrate 11 and then cutting (that is, dicing) the plurality of semiconductor packages 10. A detailed description thereof will be provided below through a manufacturing method of a semiconductor package.

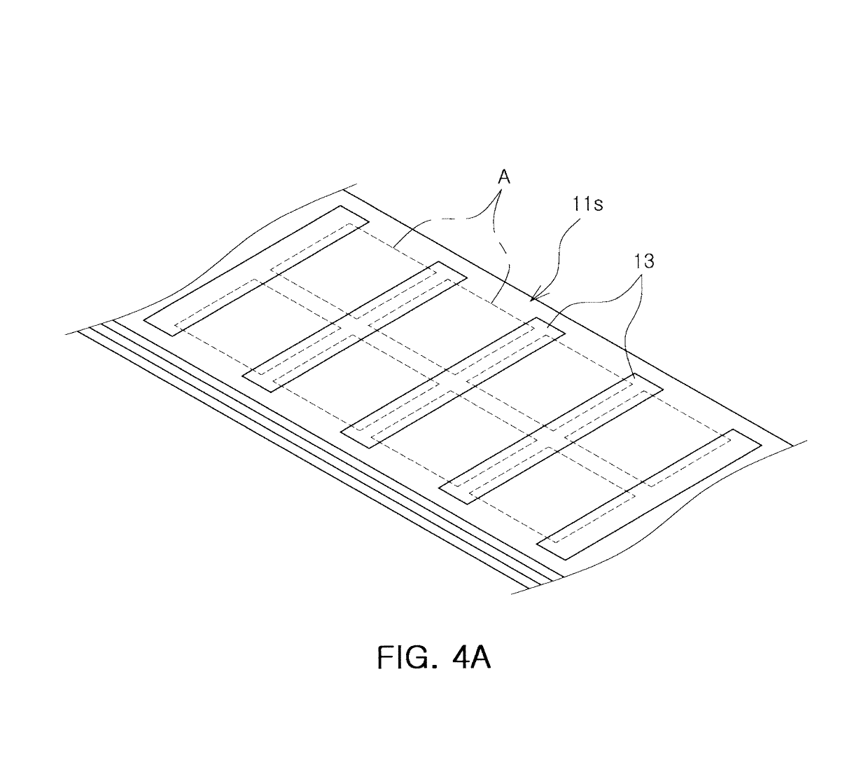

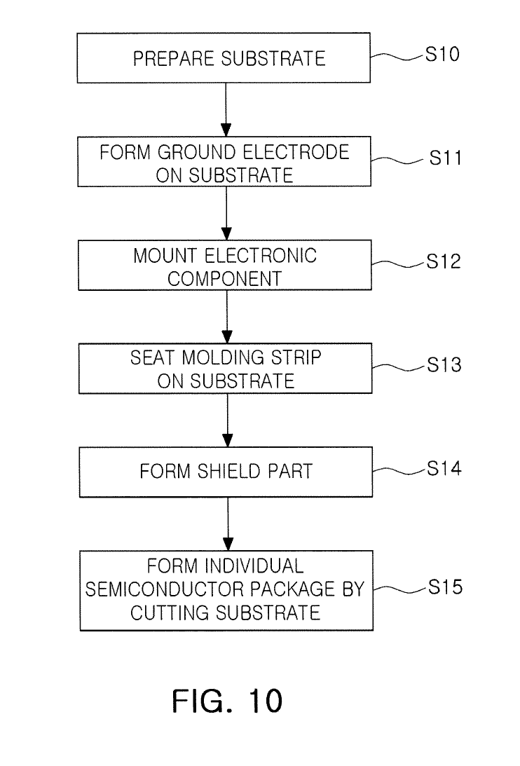

FIGS. 3 to 9B are process cross-sectional views showing a manufacturing method of a semiconductor package according to a process sequence according to an exemplary embodiment of the present invention, and FIG. 10 is a flow chart shown a manufacturing method of a semiconductor package according to an exemplary embodiment of the present invention.

First, referring to FIG. 3 based on FIG. 10, a manufacturing method of a semiconductor package according to an exemplary embodiment of the present invention starts with an operation of preparing the substrate 11 (S10).

The substrate 11 according to the exemplary embodiment of the present invention may be a multi-layer circuit substrate 11 formed with a plurality of layers, and the circuit patterns may be formed between the plurality of layers for forming electrical connections therebetween. More specifically, the circuit patterns 12, the external ground terminals 18, the mounting electrodes 20, the via-holes 17, and the like, shown in FIG. 1 may be formed.

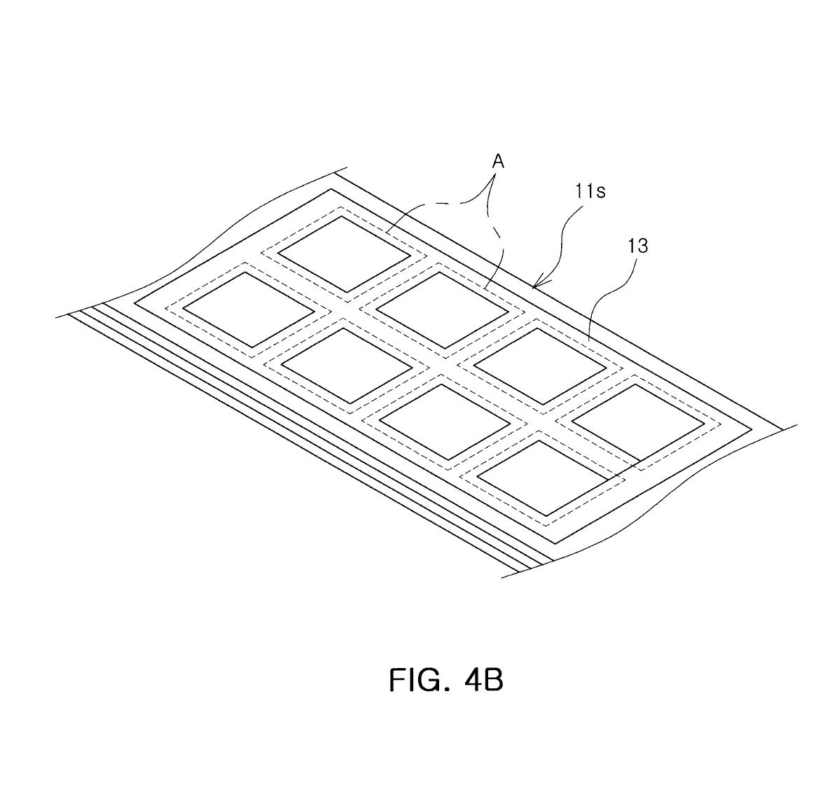

Meanwhile, as the substrate 11 according to the exemplary embodiment of the present invention, a strip-shaped substrate (hereinafter, a strip substrate 11s) is used. The strip substrate 11s is formed to have simultaneously manufactured a plurality of individual semiconductor packages 10. A plurality of individual semiconductor package regions A are divided on the strip substrate 11s, and the semiconductor package 10 is manufactured for each of the plurality of the individual semiconductor package regions (A in FIG. 4A).

Then, as shown in FIG. 4A, in an operation (S11), the ground electrodes 13 are formed on the strip substrate 11a. When the strip substrate 11s is cut out for each individual semiconductor package region A, the ground electrodes 13 may be formed along sides of the cut individual substrate 11, as described above.

However, the present invention is not limited thereto but the ground electrodes 13 may also be formed as shown in FIG. 4B. In this case, when the strip substrate 11s is cut out for each individual semiconductor package region A, the ground electrodes 13 are formed along the entire edge of the cut individual substrate 11.

Meanwhile, a method for forming the ground electrodes 13 on the substrate 11 may be performed identically to a method for forming general circuit patterns. Therefore, a detailed description thereof will be omitted.

In addition, in the manufacturing method of a semiconductor package according to the exemplary embodiment of the present invention, the ground electrodes 13 may also be formed on the substrate 11 during manufacture of the substrate 11. In this case, the operation (S11) of forming the ground electrodes 13 as described above may be omitted.

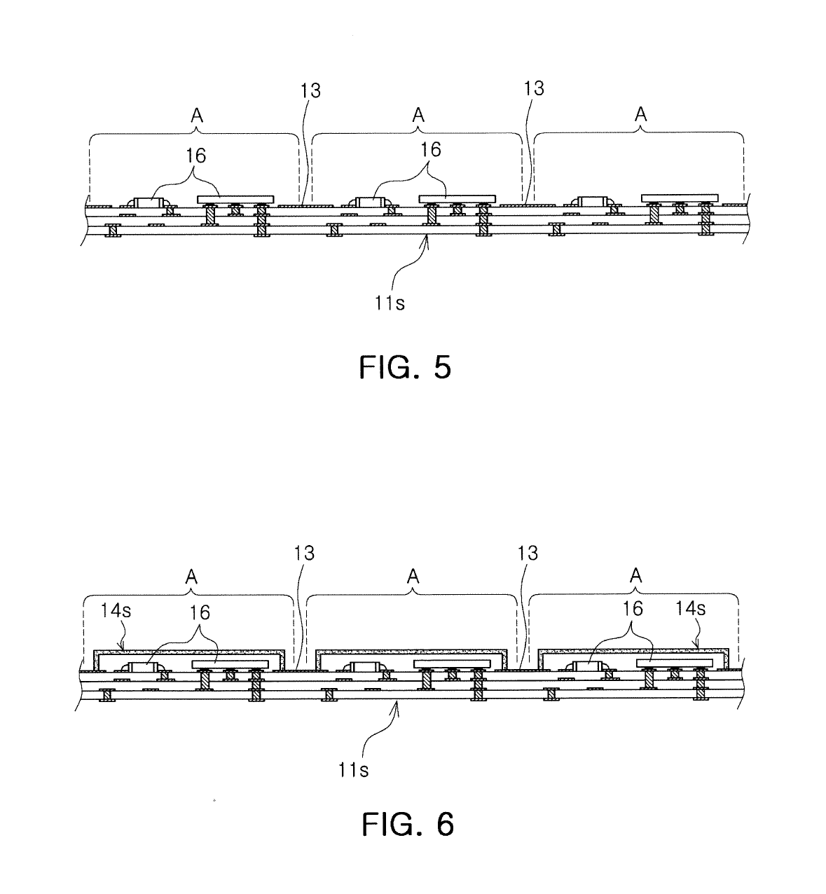

Next, as shown in FIG. 5, in an operation (S12), the electronic components 16 are mounted on one surface of the substrate 11. At this time, the electronic components 16 may be repetitively mounted on the entire individual semiconductor package regions A of the substrate 11. That is, the same kind and the same number of the electronic components may be disposed and mounted for each individual semiconductor package region A.

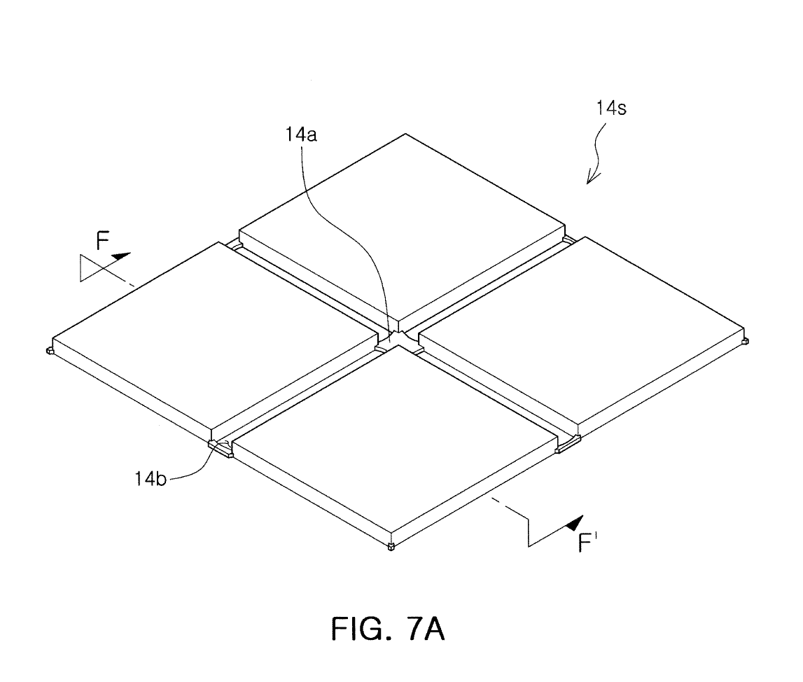

Then, as shown in FIG. 6, in an operation (S13), the molding part 14 is seated on one surface of the substrate 11. At this time, the molding part 14 according to the exemplary embodiment of the present invention may be formed by using a separately provided molding strip 14s.

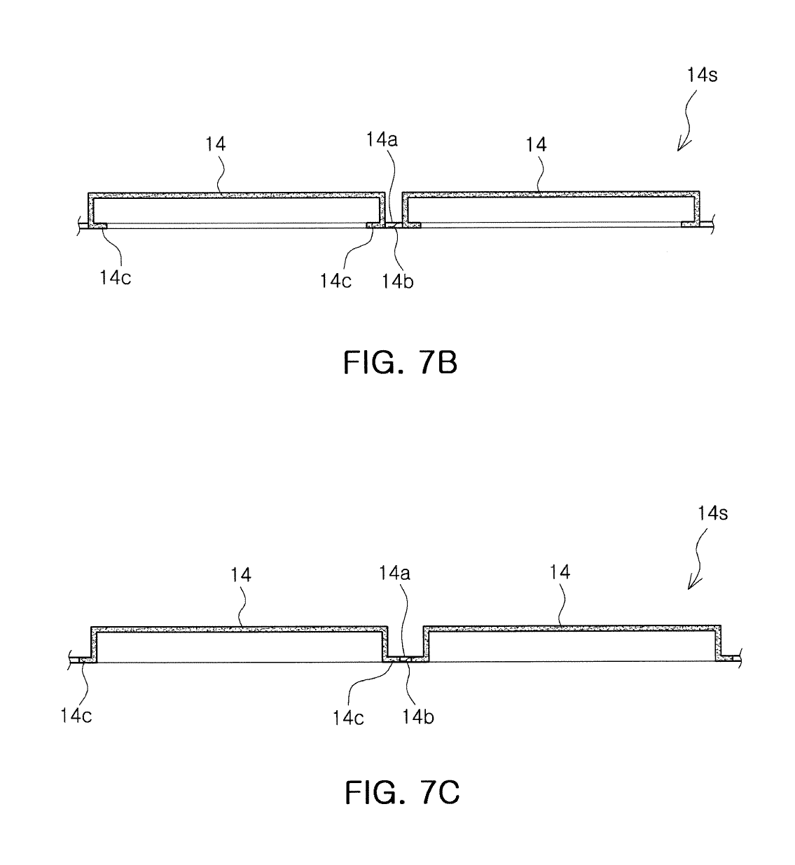

FIG. 7A is a perspective view schematically showing the strip substrate and the molding strip shown in FIG. 6. Referring to FIGS. 6 and 7A, the molding strip 14s according to the exemplary embodiment of the present invention is formed to have a corresponding shape to that of the strip substrate 11s.

The molding strip 14s is formed by connecting a plurality of molding parts 14 each individualized for each individual semiconductor package region A of the strip substrate 11s. That is, the molding parts 14 according to the exemplary embodiment of the present invention are not formed to have an integral shape by which the entirety of the strip substrate 11s is covered, but are formed to have separate shapes by which each of the molding parts 14 may be divided for each individual semiconductor package region A.

To this end, the molding strip 14s according to an exemplary embodiment of the present invention includes an interconnector 14a interconnecting the plurality of molding parts 14. The interconnector 14a interconnects tap (that is, corner) portions of each of the molding parts. Accordingly, the plurality of molding parts 14 may be formed to have an entirely interconnected integral shape. Meanwhile, the interconnector 14a has been omitted in FIG. 6 for convenience of explanation.

In addition, in the molding strip 14s according to the exemplary embodiment of the present invention, a space between two disposed adjacently interconnectors (that is, a space between two adjacent molding parts) is formed as an empty space (hereinafter, referred to as a penetration part 14b). Through the penetration part 14b, when the molding strip 14s is seated on the strip substrate 11s, the ground electrodes 13 formed on the strip substrate 11s are exposed externally. The molding strip 14s may be fixedly coupled to the strip substrate 11s through the use of an adhesive. However, the present invention is not limited thereto, but may also use a method for fixing the molding strip 14s to the strip substrate 11s by using a subsequently formed shield part 15. A detailed description thereof will be provided in an operation (S14) of forming a shield part to be described below.

Meanwhile, as described above, in the operation (S13), each of the individualized molding parts 14 is formed to have a size such that the ground electrodes 13 formed on the substrate 11 are at least partially exposed. Herein, the exposed regions (B in FIG. 1) of the ground electrodes 13 exposed externally of the molding part 14 is in contact with the shield part 15 through a subsequent process of forming the shield part 15 to be electrically connected thereto.

As described above, in the manufacturing method of a semiconductor package according to an exemplary embodiment of the present invention, the molding part 14 is formed to have individualized shapes rather than being formed to have the integral shape as in the related art, whereby a process of cutting the integral molding part into the individual molding parts through a half dicing process 14 may be omitted.

Meanwhile, in the case of using the individualized molding parts 14 as in the exemplary embodiment of the present invention, when the molding strip 14s is seated on the substrate 11, an error in arrangement between the molding strip 14s and the substrate 11 may be generated. When the molding strip 14s or the substrate 11 is biased to any one side due to the error in arrangement, the entire exposed region B of the ground electrode 13 formed on a corresponding side may be positioned internally of the molding part 14 without being exposed externally of the molding part 14.

In order to solve the defect, at least two ground electrodes 13 according to the exemplary embodiment of the present invention are formed on the substrate 11 along both sides of the substrate 11. In this case, when one of the ground electrodes 13 on any one side of the substrate is entirely positioned within the molding part 14 due to the error in arrangement, the other ground electrode 13 on the other side is further exposed externally of the molding part 14.

Accordingly, a defect in which the ground electrodes 13 and the shield part 15 are not electrically connected in an operation of forming the shield part to be described below due to the error in arrangement generated in the operation of forming the molding part 14 may be prevented.

Meanwhile, the molding part 14 according to an exemplary embodiment of the present invention is not limited to the exemplary embodiment of the present invention, but various applications thereof may be made. For example, as shown in FIGS. 7B and 7C, the molding part 14 may also be configured to include flanges on a lower end thereof. FIGS. 7B and 7C, which are views showing a molding strip according to another exemplary embodiment of the present invention, shows a cross section taken along the line F-F′ of FIG. 7A.

Referring to this, a case in which flanges 14c are formed internally of the molding part 14 is shown by way of example in FIG. 7B, and a case in which the flanges 14c are formed externally of the molding part 14 is shown by way of example in FIG. 7C. At this time, both of the molding parts 14 shown in FIGS. 7B and 7C include the penetration part 14b similar to the molding part 14 shown in FIG. 7A.

When the flanges 14c are formed on the lower end of the molding part 14, the molding part 14 is in contact with the substrate 11, while having a wider contact area with the substrate 11, whereby the molding part 14 may be further firmly coupled to the substrate 11.

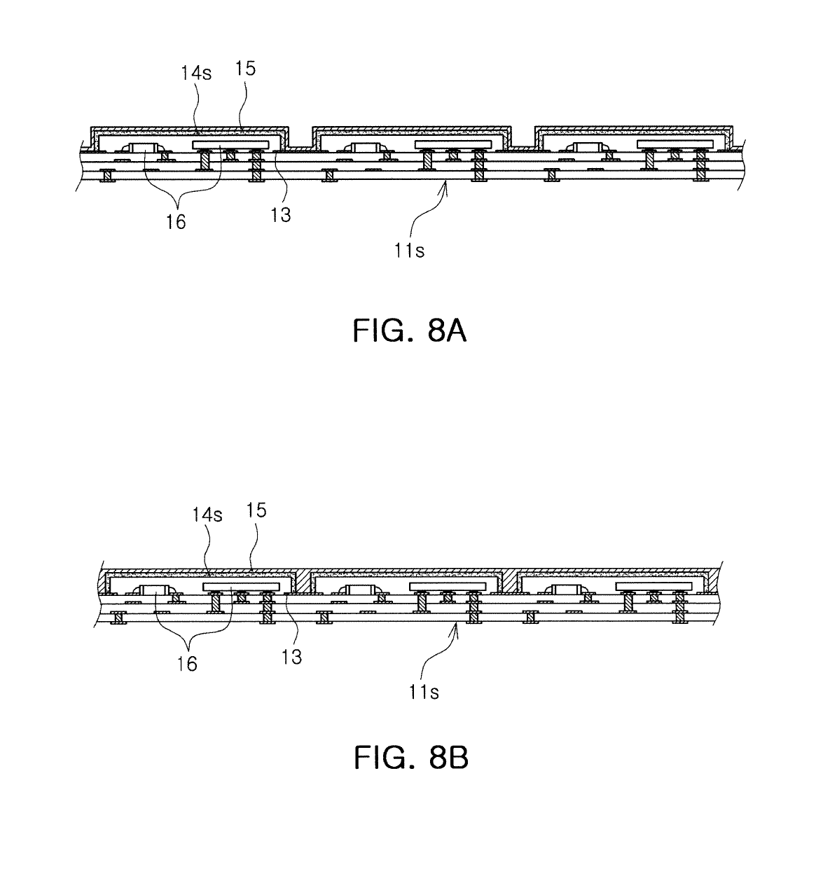

Next, as shown in FIG. 8A, in an operation (S14), the shield part 15 is formed on the outer surface of the molding strip 14s. At this time, the shield part 15 is formed over the upper surface of the strip substrate 11a on which the molding strip 14s is seated.

That is, the shield part 15 is formed over the upper surface and the sides of each of the molding parts 14, and is also formed between the individual molding parts 14, that is, on the penetration part 14b as well as the outer surfaces of the molding parts 14. Accordingly, the shield part 15 is also formed on the ground electrodes 13 exposed externally due to the penetration part 14b of the molding part 14, whereby the shield part 15 is electrically connected to the ground electrodes 13.

The shield part 15 may be the metal thin film. In this case, the metal thin film may be formed by using the conformal coating method. The conformal coating method is not only a process appropriate for forming a uniform coating film but also has advantages such as cheap cost, excellent productivity, environment-friendly characteristics, as compared to other thin film formation processes (for example, an electroplating method, an electroless plating method, a sputtering method). When the conformal coating method is used, the space between the adjacent individual molding parts 14 remains as the empty space.

However, the present invention is not limited thereto but the shield part 15 may also be formed using the screen printing method, as shown in FIG. 8B. When the screen printing method is used, the space between the adjacent individual molding parts 14 is filled with conductive pastes rather than remaining as the empty space as in FIG. 8A, thereby the shield part 15 to be formed.

In addition, the shield part 15 according to the exemplary embodiment of the present invention may be formed on the molding part 14 and the substrate 11 to serve to fixedly bond the molding part 14 to the substrate 11, as described above. In this case, the shield part 15 may be formed by applying a conductive adhesive onto the molding part 14 and the substrate 11.

Meanwhile, in the manufacturing method of a semiconductor package according to an exemplary embodiment of the present invention, the shield part 15 is formed, and then a plasma treatment process is performed on the shield part 15 in order to improve abrasion resistance and corrosion resistance of a surface of the shield part 15.

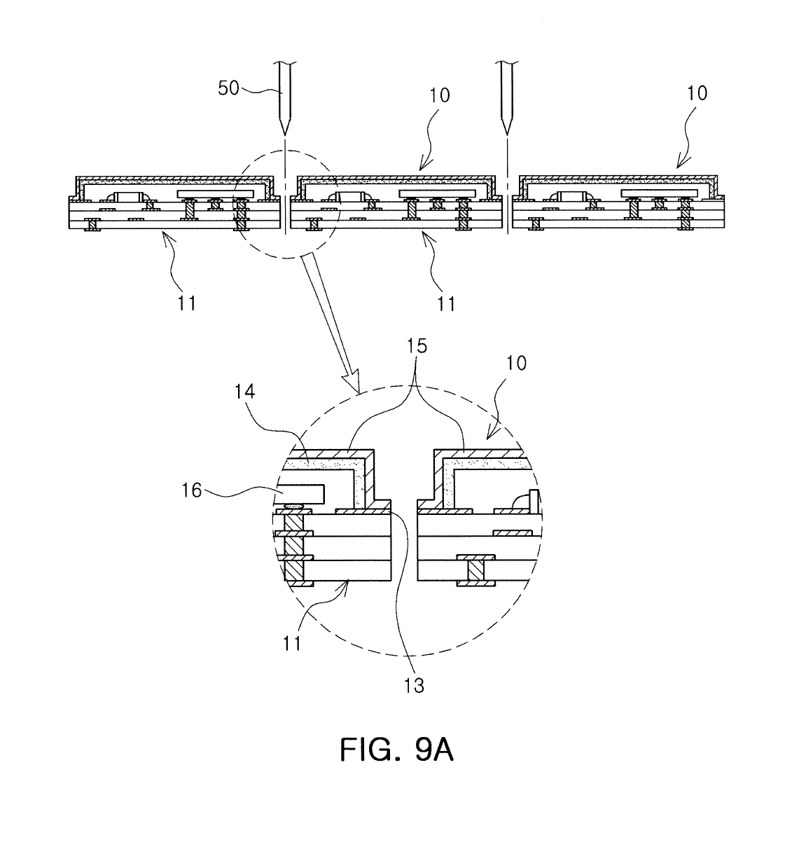

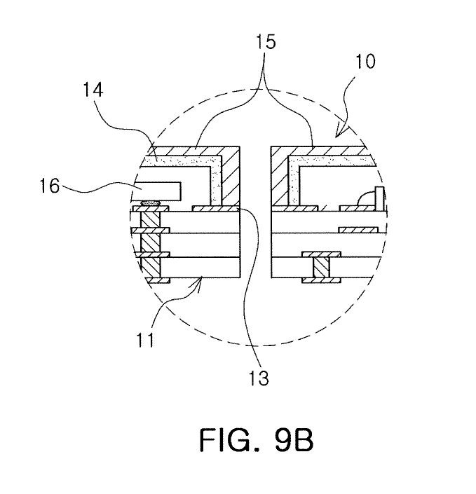

Then, as shown in FIG. 9A, in an operation (S15), the individual semiconductor packages 10 are formed by cutting the strip substrate 11s. A cutting process in the operation (S15) is performed such that the upper and lower surfaces of the substrate 11 having the shield part 15 formed thereon are cut off at once using a blade 50. At the same time, the blade 50 removes the interconnector 14a of the molding strip 14s.

FIG. 9A shows an example of cutting the strip substrate 11s shown in FIG. 8A. That is, a case in which a cutting surface of the substrate 11 is formed on a plane different from a vertical outer surface of the shield part 15 is shown by way of example in FIG. 9A.

As described above, the shield part 15 according to the exemplary embodiment of the present invention is electrically connected to the ground electrode 13s through the entire exposed region (B in FIG. 1) of the ground electrodes 13, whereby electrical reliability of the semiconductor package 11 may be secured.

Meanwhile, FIG. 9B shows an example of cutting the strip substrate 11s shown in FIG. 8B. In FIG. 9B, the vertical outer surface of the shield part 15 and the cutting surface of the substrate are on substantially the same plane. Also in this case, the shield part 15 of the semiconductor package 11 is electrically connected to the ground electrodes 13 through the entire exposed region (B in FIG. 1) of the ground electrodes 13 exposed externally of the molding part 14. Accordingly, the electrical reliability of the semiconductor package 11 may be secured. In addition, the shield part 15 formed the side of the molding part 14 is formed to have a relatively thick thickness, whereby the damage of the shield part 15 due to an external environment may be minimized.

As set fort above, according to the exemplary embodiments of the present invention, the ground electrode formed on the upper surface of the substrate is used to ground the shield part for shielding the electromagnetic waves, whereby the shield part may be easily grounded.

In addition, according to the exemplary embodiments of the present invention, the molding part is formed to have the cap shape including the empty space formed internally, whereby the empty space is formed between the electronic components. Therefore, although the high temperature is applied to the semiconductor package, internal pressure is released due to the empty space formed internally of the molding part, whereby damage of the semiconductor package due to the internal pressure as in the related art may be prevented.

Further, according to the exemplary embodiments of the present invention, the molding strip formed by integrally connecting the molding parts each divided for each individual semiconductor package region is used during the formation of the molding part. Accordingly, the cutting surfaces of the individual semiconductor packages may be cleanly formed and the sizes of each of the semiconductor packages may be uniformly formed, as compared to the method of primarily cutting (for example, half dicing) portions (that is, molding part regions) of the substrate having the molding part formed thereon, to form the shield part, and then secondarily cutting remaining non-cut portions according to the related art. Furthermore, such a manufacturing process is omitted, whereby manufacturing costs may be reduced.

In addition, according to the exemplary embodiments of the present invention, the shield part is electrically connected to the ground electrodes formed on the upper portion of the substrate. According to the related art, the method of exposing the electrode to the side of the substrate and electrically connecting the shield part thereto has been mainly used. In the case of the related art, the shield part has also been formed on the side of the substrate to cause a defect in which the shield part formed on the side of the substrate is electrically connected to other electrodes than the ground electrodes to be conducted. However, according to the exemplary embodiments of the present invention, the shield part is formed only on the outer surface of the molding part, whereby the reliability thereof may be secured, as compared to the method according to the related art.

The semiconductor package and the manufacturing method thereof according to the exemplary embodiments of the present invention as described above are not limited to the aforementioned embodiment but various applications can be made. In addition, although the above-mentioned exemplary embodiments of the present invention have described the semiconductor package having the shield part by way of example, the present invention is not limited thereto, but various applications may be made if it is an apparatus including the shield part for shielding the electromagnetic waves.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor package, comprising:
a substrate having ground electrodes formed on an upper surface thereof;
at least one electronic component mounted on the upper surface of the substrate;
an insulating molding part including an internal space in which the electronic component is accommodated, and fixed to the substrate such that at least a portion of the ground electrode is externally exposed; and
a conductive shield part closely adhered to the molding part to cover an outer surface of the molding part and electrically connected to the externally exposed ground electrodes.

2. The semiconductor package of claim 1, wherein the ground electrodes are formed on the substrate along edges thereof.

3. The semiconductor package of claim 1, wherein the molding part is formed to have a cap shape.

4. The semiconductor package of claim 1, wherein the molding part includes flanges protruded to be parallel with the upper surface of the substrate on a lower end surface thereof being in contact with the upper surface of the substrate.

5. A manufacturing method of a semiconductor package, the manufacturing method comprising:
preparing a substrate having ground electrodes formed on an upper surface thereof;
mounting electronic components on the upper surface of the substrate;
seating a molding part having a cap shape on the substrate such that a portion of the ground electrodes is externally exposed; and
forming a conductive shield part on an outer surface of the molding part, the conductive shield part being electrically connected to the externally exposed ground electrodes.

6. The manufacturing method of claim 5, wherein the forming of the conductive shield part includes forming the conductive shield part through a conformal coating method.

7. The manufacturing method of claim 5, wherein the forming of the conductive shield part includes forming the conductive shield part through a screen printing method.

8. The manufacturing method of claim 5, wherein the ground electrodes are formed on the substrate along edges thereof.

9. The manufacturing method of claim 5, wherein the preparing of the substrate includes preparing a strip substrate having a plurality of individual semiconductor package regions formed thereon.

10. The manufacturing method of claim 9, wherein the mounting of the electronic components includes mounting the electronic components for each of the plurality of individual semiconductor package regions.

11. The manufacturing method of claim 10, wherein the seating of the molding part includes seating a molding strip formed by connecting a plurality of molding parts on the strip substrate.

12. The manufacturing method of claim 11, wherein the forming of the conductive shield part includes forming the conductive shield part over the upper surface of the strip substrate on which the molding strip is seated.

13. The manufacturing method of claim 12, further comprising dividing the strip substrate into individual semiconductor packages by cutting the strip substrate according to the individual semiconductor package regions using a blade after the forming of the shield part.

14. The manufacturing method of claim 13, wherein the dividing of the strip substrate includes cutting the strip substrate such that a cutting surface of the cut substrate and a side of the shield part are positioned on different planes.

15. The manufacturing method of claim 5, wherein the molding part is formed to have a smaller area than that of the substrate.

16. The manufacturing method of claim 5, wherein the seating of the molding part includes adhering the molding part to the substrate with an adhesive.

17. The manufacturing method of claim 5, wherein the shield part is a conductive adhesive, and the molding part is fixedly bonded to the substrate by the shield part.

18. The manufacturing method of claim 13, wherein the molding strip includes:
a plurality of molding parts; and
a plurality of interconnectors interconnecting tap portions of the molding parts,
an empty space being formed between two adjacently disposed interconnectors.

19. The manufacturing method of claim 18, wherein a width of the empty space formed between the interconnectors is larger than a thickness of the blade.
